(19) United States
(12) Patent Application Publication
(10) Pub. No.: US 2025/0331135 A1
(43) Pub. Date: Oct. 23, 2025

(54) NEW TYPE OF HIGH-EFFICIENCY LIQUID COOLING CABINET FOR DATA CENTER SERVER

(71) Applicant: TIANJIN UNIVERSITY OF COMMERCE, Tianjin (CN)

(72) Inventors: Yulin WANG, Tianjin (CN); Wei HE, Tianjin (CN); Shengchun LIU, Tianjin (CN); Yurong YANG, Tianjin (CN); Shuailing LIU, Tianjin (CN)

(73) Assignee: TIANJIN UNIVERSITY OF COMMERCE, Tianjin (CN)

(21) Appl. No.: 18/861,617

(22) PCT Filed: Apr. 3, 2023
(86) PCT No.: PCT/CN2023/085824

§ 371 Date: Oct. 30, 2024

(30) Foreign Application Priority Data
May 5, 2022 (CN) 202210481826.9

(51) Int. Cl. H05K 7/20

(52) U.S. Cl. CPC H05K 7/20781; H05K 7/20736

(57) ABSTRACT

A new type of high-efficiency liquid cooling cabinet for a data center server is provided. A new type of high-efficiency liquid cooling cabinet for a data center server includes a base plate, a cabinet, main boards, and memory strips, etc.; and the cabinet is welded on the upper part of the base plate, the front, left and right sides of the cabinet are open settings, seven main boards are evenly distributed up and down in the cabinet. By connecting the water inlet pipe from the outdoor to the coolant, the coolant enhances the convective heat transfer to cool the bottom chips, and the hot wind in the holes is cooled by the coolant flowing through the cavity of the six-hole heat-dissipation cavity device, finally, it is ensured that the main board and the memory strips may be cooled below the safe temperature simultaneously.

### CROSS REFERENCE TO THE RELATED APPLICATIONS

This application is the national phase entry of International Application No. PCT/CN2023/085824, filed on Apr. 3, 2023, which is based upon and claims priority to Chinese Patent Application No. 202210481826.9, filed on May 5, 2022, the entire contents of which are incorporated herein by reference.

### TECHNICAL FIELD

The present disclosure relates to a liquid cooling cabinet, and in particular to a new type of high-efficiency liquid cooling cabinet for a data center server.

### BACKGROUND

A development trend of the current data center is: on the one hand, the scale of development is getting larger and larger, on the other hand, the demand for computing chip power is getting higher and higher. Then two issues would arise: the first is to ensure the effective cooling of the electronic components at the interior of the high heat flux power cabinet, so that the electronic components work at a safe working temperature; and the second is that the energy consumption of the data center cooling system is becoming larger and larger, and it is necessary to develop a cooling system with high efficiency and low energy consumption. At present, the mainstream of data center cooling is air cooling. As the heat flux density of the chip increases, the air cooling is increasingly unable to meet the requirements. Therefore, liquid cooling technology has been developed in recent years. There are three types of liquid cooling technology: immersion-type liquid cooling, spray-type liquid cooling, and cold plate-type liquid cooling. Due to the direct contact between the cooling medium and the electronic components in the first two, the implementation difficulty and requirements are higher. Because of the indirect contact between the radiator and the heating elements, the cold plate type is easy to carry out transformation and implementation of the existing data center cooling system, and it is the current mainstream liquid cooling method.

The defects and shortcomings of the current technology are: at present, the technical solution of the cold plate-type liquid cooling in the data center is: the heat dissipation of the chip is achieved by attaching a liquid cooling radiator to the CPU, the coolant in the radiator comes from an external cold source, memory cooling is achieved by blowing cold air through the memory through the fan arranged on the substrate, while the cold wind comes from the liquid cooling backplane arranged on the cabinet backplane to achieve, and the coolant in the backplane also comes from an external cold source. As the cold wind blows through the memory, the wind temperature may rise, and then it may bring heat to the environment when blowing out of the cabinet, therefore, a room-level air conditioning system is generally arranged. So the cold plate type-cooling system in the cabinet room needs to arrange three kinds of cooling devices, a chip liquid-cooled radiator, a backplane liquid-cooled radiator for cooling memory, and a room-level air conditioner. The entire cooling system has multiple working substance circulation pipelines and has problems including mismatch of working substance diffluent, complex assembly, inconvenient operation adjustment, high energy consumption, and high system cost.

Therefore, it is necessary to invent a new type of high-efficiency liquid cooling cabinet for a data center server, which can ensure that the wind inlet and wind outlet temperatures of the cabinet are basically the same, does not dissipate heat to the room, does not increase the environmental cooling load, and can simultaneously achieve memory and chip cooling.

### SUMMARY

In order to overcome the shortcomings of the current high heat flux chip cooling and memory cooling using two sets of devices and complex high energy consumption by the need to arrange a heat dissipating device of a cabinet room air conditioner, the technical problem is to provide a new type of high-efficiency liquid cooling cabinet for a data center server, which ensures that the inlet and outlet temperatures of the cabinet are basically the same, does not dissipate heat to the room, does not increase the environmental cooling load, and can simultaneously achieve memory and chip cooling.

The technical solutions of the present disclosure are: a new type of high-efficiency liquid cooling cabinet for a data center server includes a base plate, a cabinet, main boards, memory strips, chips, air cooling devices and air inlet regulating devices, the cabinet is welded on the upper part of the base plate, the front, left and right sides of the cabinet are open settings, seven main boards are evenly distributed in the cabinet up and down, four groups of memory strips are arranged on each main board, the memory strips are grouped into six, on each motherboard, two chips are arranged on each main board symmetrically in front and back, each main board is arranged with one air cooling device to dissipate heat from the main board, air inlet regulating devices are arranged on the left and right sides of the cabinet, and the left and right air intake volume may be adjusted by the air inlet regulating devices.

Further, the air cooling device includes fans, wind scoopers, six-hole heat-dissipation cavity devices and spacer plates, two sets of cooling fans are arranged on the upper left side of each main board, the cooling fans are grouped into six, four wind scoopers are arranged on each main board, the wind scooper covers each group of memory strips, the wind scooper draws the wind from left to right, five sliding grooves are arranged on the upper part of the wind scooper, each main board is arranged with four six-hole heat-dissipation cavity devices, the six-hole heat-dissipation cavity devices are located on the right side of each group of memory strips, the interior of the six-hole heat-dissipation cavity device may be used for cooling liquid circulation, each wind scooper is arranged with five spacer plates, and the spacer plates are located between every two memory strips.

Further, the air inlet regulating device includes long axes, grille plates, column wheels, racks, circular shafts, missing-tooth wheels and deflector rods, the left and right openings of the cabinet are evenly distributed with the long axes in a longitudinal direction, the long axes are arranged horizontally, both ends of the long axes are embedded in the cabinet, one grille plate is fixedly arranged on each long axis, one column wheel is fixed at both ends of each long axis, two racks are arranged in the left and right openings of the cabinet in a sliding type, respectively, each rack is engaged with the column wheel longitudinally distributed at one end of the corresponding long axis, one circular shaft is arranged on the upper side of each rack facing outward, one missing-tooth wheel is rotatably arranged on the circular shaft, one toothed side of the missing-tooth wheel is engaged with one rack, the other side of the missing-tooth wheel is fixedly connected to one deflector rod, the deflector rod is used to shift the missing-tooth wheel, and the deflector rod penetrates out of the cabinet.

Further, the liquid cooling cabinet further includes a water cooling device, the water cooling device includes U-shaped pipes, a horizontal pipe, a straight pipe, L-shaped pipes, a water inlet vertical pipe, a water inlet pipe, a water outlet vertical pipe and a water outlet pipe, U-shaped pipes are arranged on the front and back two sides of the upper part of each six-hole heat-dissipation cavity device, the two U-shaped pipes on the front side link and connect the front six-hole heat-dissipation cavity devices, the two U-shaped pipes on the rear side link and connect the rear six-hole heat-dissipation cavity devices, the horizontal pipe is arranged between the two U-shaped pipes in the middle, the horizontal pipe connects the two U-shaped pipes in the middle, the middle right side of the horizontal pipe is connected to the straight pipe, the front and rear U-shaped pipes are connected to L-shaped pipes, the water inlet vertical pipe is arranged at the front and back two sides of the right part of the cabinet, the water inlet vertical pipe connects the longitudinal L-shaped pipes on the front and back sides of the right part of the cabinet, the middle of the water inlet vertical pipe is connected to the water inlet pipe, the water inlet pipe discharges the external coolant in, the water outlet vertical pipe is arranged in the middle of the right side of the cabinet, the water outlet vertical pipe connects the longitudinal straight pipe in the middle of the right side of the cabinet, the middle of the water outlet vertical pipe is connected to the water outlet pipe, and the water outlet pipe discharges the internal coolant out.

Further, the liquid cooling cabinet further includes a wind direction adjusting device, the wind direction adjusting device includes rotation shafts, guide plates, torsion springs, sliders, limit blocks, fixture blocks, spheres, small springs, and long blocks, ten rotation shafts are rotatably arranged under each wind scooper, every two rotation shafts are located on both sides of the front and back of one spacer plate, the guide plate is fixedly arranged on each rotation shaft, the torsion spring is arranged between the guide plate and the wind scooper, the slider is arranged in the sliding groove of each wind scooper, the upper part of the slider is open setting, the limit block is fixedly connected to the bottom of each slider, the limit block is used to adjust an angle of the guide plate, the fixture block is arranged at the upper opening of the slider, the bottom of the fixture block is arranged to be wide in the middle and narrow on both sides, the spheres are arranged on both sides of the fixture block, the spheres pass through the front and rear sides of the slider, the small springs are arranged between the left and right sides of the fixture block and the left and right sides of the interior of the slider, one long block is arranged at the upper part of each wind scooper, and each long block connects five sliders in the sliding groove of the lower wind scooper, the long block is used to synchronously control five sliders, two circular holes are arranged on both sides of the sliding groove of each wind scooper, and the circular holes are matched with the spheres in the sliders.

Further, the liquid cooling cabinet further includes heat transfer fins, the heat transfer fins are arranged at the inner bottom of the six-hole heat-dissipation cavity device on each main board, the heat transfer fins are located directly above each chip, and thermal conductive materials are coated between the chip and the six-hole heat-dissipation cavity device.

Further, the liquid cooling cabinet further includes a bracket, the middle of the right part of the cabinet is arranged with the bracket by bolts, and the bracket fixes the water inlet pipe and the water outlet pipe, which may effectively avoid damage to the water inlet pipe and the water outlet pipe when moving the cabinet.

The beneficial effects are: according to the present disclosure, 1. the wind blown by the cooling fans may enter into the wind scooper, the spacer plate in the wind scooper separates the wind from each other and evenly dissipates heat for each memory strip, then the wind passes through the left six-hole heat-dissipation cavity device, and enters into the right wind scooper and dissipates the heat of the right memory strip, then the wind is blown out through the right six-hole heat-dissipation cavity device, in this way, a heat dissipation source may be realized to cool the main board and memory strips at the same time. 2. By connecting the water inlet pipe from the outdoor to the coolant, the coolant enhances the convective heat transfer to cool the bottom chips, and the hot wind in the holes is cooled by the coolant flowing through the cavity of the six-hole heat-dissipation cavity device, finally, it is ensured that the main board and the memory strips may be cooled below the safe temperature simultaneously, and at the same time, and it is ensured that the air temperature inhaled and discharged by the grille plate is equal, in this way, circulating cooling may be realized. 3. By pushing the long blocks to change the direction of the wind, the heat dissipation effect of the memory strips may be strengthened or the hot wind may be discharged faster.

### BRIEF DESCRIPTION OF THE DRAWINGS

FIG. 1 is a first three-dimensional structure diagram of the present disclosure.

FIG. 2 is a second three-dimensional structure diagram of the present disclosure.

FIG. 3 is a structure diagram of an air inlet regulating device of the present disclosure.

FIG. 4 is a schematic diagram of part A of the present disclosure.

FIG. 5 is a first structure diagram of a water cooling device of the present disclosure.

FIG. 6 is a second structure diagram of a water cooling device of the present disclosure.

FIG. 7 is a first structure diagram of a wind direction regulating device of the present disclosure.

FIG. 8 is a second structure diagram of a wind direction regulating device of the present disclosure.

FIG. 9 is a third structure diagram of a wind direction regulating device of the present disclosure.

FIG. 10 is a fourth structure diagram of a wind direction regulating device of the present disclosure.

Names and serial numbers of the parts in the drawings: 1. base plate; 2. cabinet; 3. main board; 4. memory chip; 41. chip; 5. air cooling device; 51. fan; 52. wind scooper; 53. six-hole heat-dissipation cavity device; 54. spacer plate; 6. air inlet regulating device; 61. long axis; 62. grille plate; 63. column wheel; 64. rack; 65. circular shaft; 66. missing-tooth wheel; 67. deflector rod; 7. water cooling device; 71. U-shaped pipe; 72. horizontal pipe; 73. straight pipe; 74. L-shaped pipe; 75. water intake vertical pipe; 76. water intake pipe; 77. water outtake vertical pipe; 78. water outtake pipe; 8. wind direction adjusting device; 81. rotation shaft; 82. guide plate; 83. torsion spring; 85. slider; 84. limit block; 86. fixture block; 87. sphere; 88. small spring; 89. long block; 810. circular hole; 9. heat transfer fin; and 10. bracket.

### DETAILED DESCRIPTION OF THE EMBODIMENTS

The following is a detailed description of the preferred technical solutions of the present disclosure in combination with the drawings.

### Embodiment

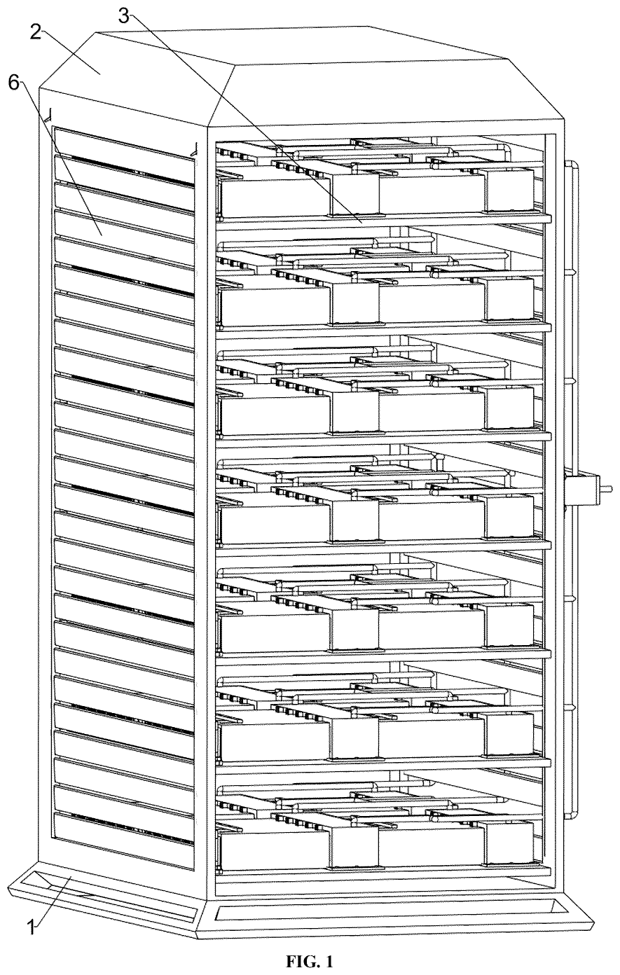

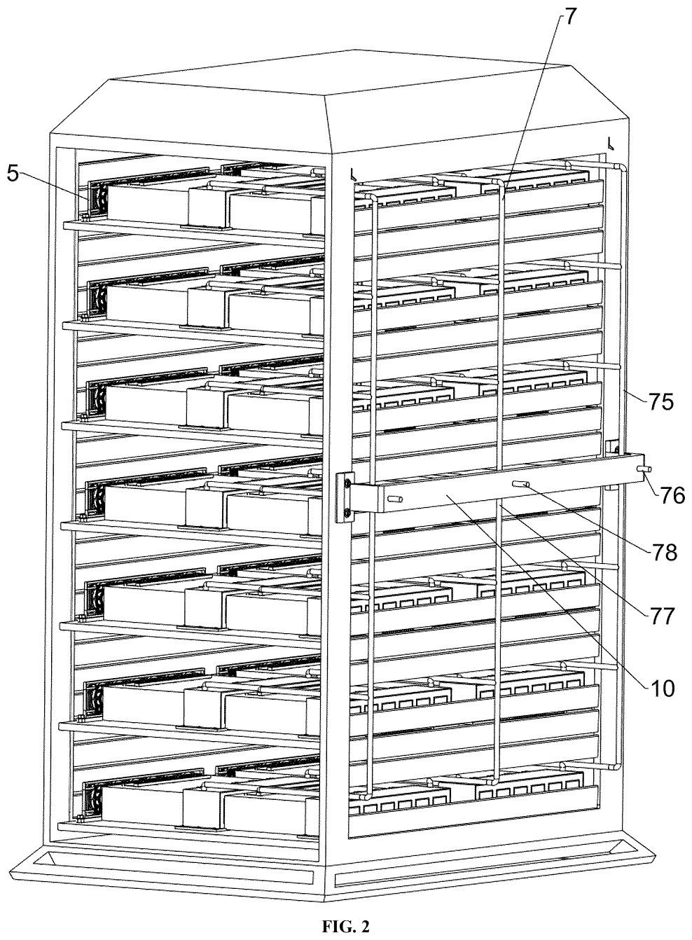

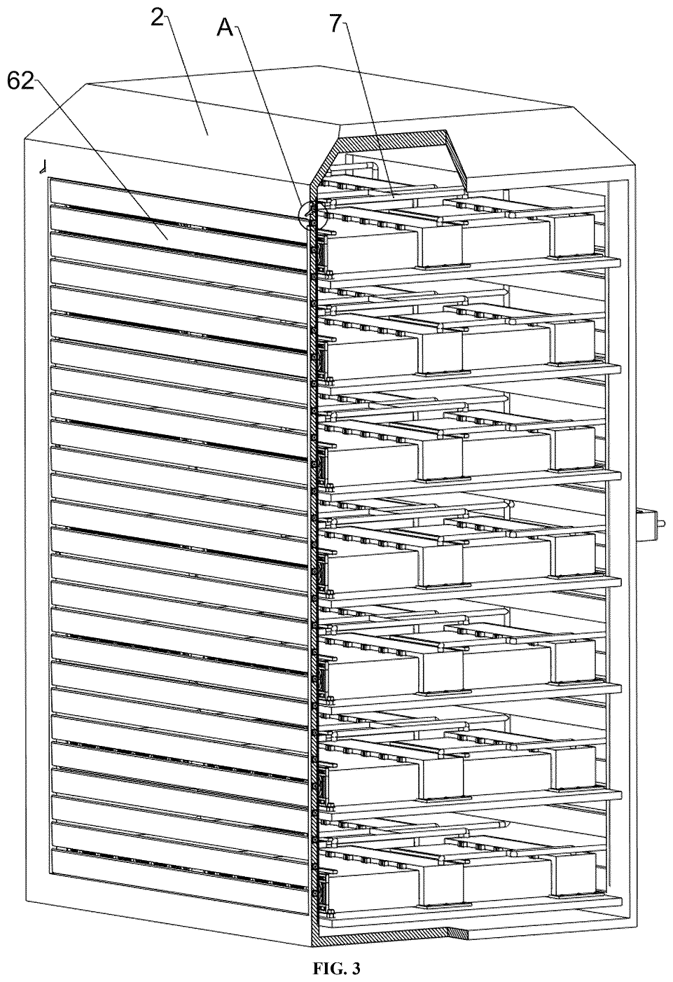

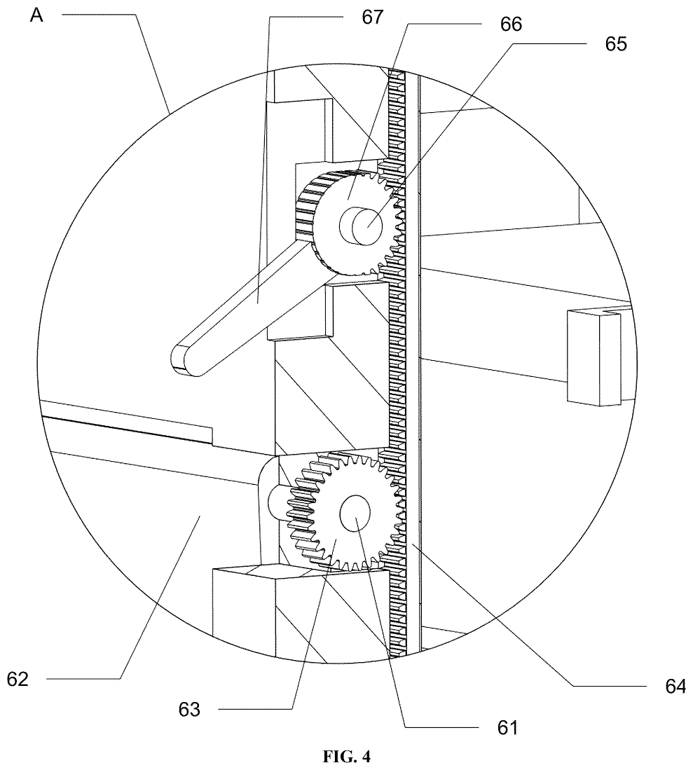

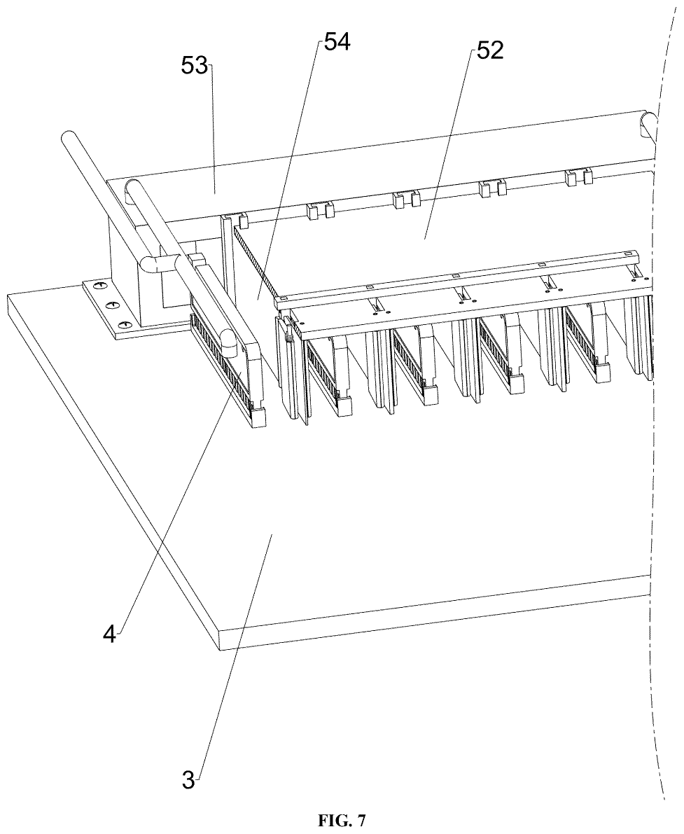

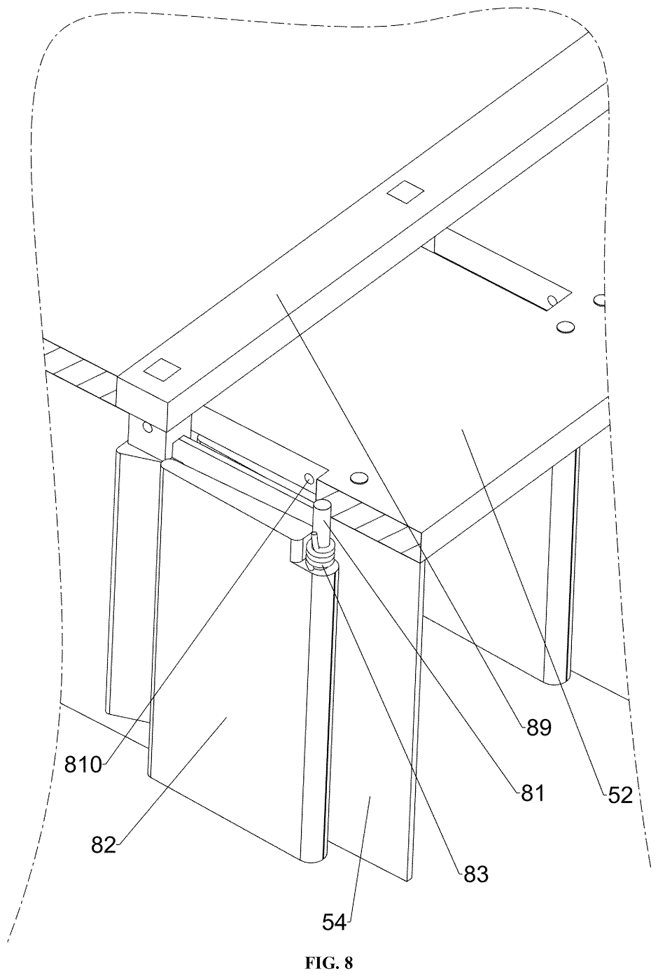

A new type of high-efficiency liquid cooling cabinet for a data center server, as shown in FIGS. 1-7, including a base plate 1, a cabinet 2, main boards 3, memory strips 4, chips 41, air cooling devices 5 and air inlet regulating devices 6, the cabinet 2 is welded on the upper part of the base plate 1, the front, left and right sides of the cabinet 2 are open settings, seven main boards 3 are evenly distributed in the cabinet 2 up and down, four groups of memory strips 4 are arranged on each main board 3, the memory strips 4 are grouped into six, two chips 41 are arranged on each main board 3 symmetrically in front and back, each main board 3 is arranged with one air cooling device 5 to dissipate heat from the main board 3, air inlet regulating devices 6 are arranged on the left and right sides of the cabinet 2, and the left and right air intake volume may be adjusted by the air inlet regulating devices 6.

The air cooling device 5 includes fans 51, wind scoopers 52, six-hole heat-dissipation cavity devices 53 and spacer plates 54, two sets of cooling fans 51 are arranged on the upper left side of each main board 3, the cooling fans 51 are grouped into six, four wind scoopers 52 are arranged on each main board 3, the wind scooper 52 covers each group of memory strips 4, the wind scooper 52 draws the wind from left to right, five sliding grooves are arranged on the upper part of the wind scooper 52, each main board 3 is arranged with four six-hole heat-dissipation cavity devices 53, the six-hole heat-dissipation cavity devices 53 are located on the right side of each group of memory strips 4, the interior of the six-hole heat-dissipation cavity device 53 may be used for cooling liquid circulation, each wind scooper 52 is arranged with five spacer plates 54, and the spacer plates 54 are located between every two memory strips 4.

The air inlet regulating device 6 includes long axes 61, grille plates 62, column wheels 63, racks 64, circular shafts 65, missing-tooth wheels 66 and deflector rods 67, the left and right openings of the cabinet 2 are evenly distributed with the long axes 61 in a longitudinal direction, the long axes are arranged horizontally, both ends of the long axes 61 are embedded in the cabinet 2, one grille plate 62 is fixedly arranged on each long axis 61, one column wheel 63 is fixed at both ends of each long axis 61, two racks 64 are arranged in the left and right openings of the cabinet 2 in a sliding type, respectively, each rack 64 is engaged with the column wheel 63 longitudinally distributed at one end of the corresponding long axis 61, one circular shaft 65 is arranged on the upper side of each rack 64 facing outward, one missing-tooth wheel 66 is rotatably arranged on the circular shaft 65, one toothed side of the missing-tooth wheel 66 is engaged with one rack 64, the other side of the missing-tooth wheel 66 is fixedly connected to the deflector rod 67, the deflector rod 67 is used to shift the missing-tooth wheel 66, and the deflector rod 67 penetrates out of the cabinet 2.

Firstly, an operator starts the cooling fans 51, the cooling fan 51 begin to rotate, the wind blown by the cooling fans 51 passes through the left wind scooper 52 to dissipate the heat of the left memory strip 4, when the wind enters into the wind scooper 52, the spacer plate 54 in the wind scooper 52 separates the wind from each other and evenly dissipates heat for each memory strip 4, then the wind passes through the left six-hole heat-dissipation cavity device 53, and enters into the right wind scooper 52 and dissipates the heat of the right memory strip 4, then the wind is blown out through the right six-hole heat-dissipation cavity device 53. When it is necessary to adjust the entrance to be larger, both sides of the deflector rods 67 are driven up, the left deflector rod 67 drives the missing-tooth wheel 66 to rotate clockwise around the circular shaft 65, the right deflector rod 67 drives missing-tooth wheel 66 to rotate anticlockwise around the circular shaft 65, the rotation of the missing-tooth wheels 66 on both sides drives the racks 64 to move down, the left rack 64 moves down to drive the column wheel 63 to rotate clockwise, the right rack 64 moves down to drive the column wheel 63 to rotate anticlockwise, the clockwise rotation of the left column wheel 63 drives the long axis 61 wheel to rotate clockwise, the anticlockwise rotation of the right column wheel 63 drives the anticlockwise rotation of the long axis 61 wheel, the clockwise rotation of the left long axis 61 wheel drives the grille plates 62 to rotate to the left to be opened around the long axis 61, the anticlockwise rotation of the right long axis 61 wheel drives the grille plates 62 to rotate to the right to be opened around the long axis 61. When it is necessary to adjust the entrance to be smaller, both sides of the deflector rods 67 are driven down, the left deflector rod 67 drives the missing-tooth wheel 66 to rotate anticlockwise around the circular shaft 65, the right deflector rod 67 drives missing-tooth wheel 66 to rotate clockwise around the circular shaft 65, the rotation of the missing-tooth wheels 66 on both sides drives the racks 64 to move up, the left rack 64 moves up to drive the column wheel 63 to rotate anticlockwise, the right rack 64 moves up to drive the column wheel 63 to rotate clockwise, the anticlockwise rotation of the left column wheel 63 drives the long axis 61 wheel to rotate anticlockwise, the clockwise rotation of the right column wheel 63 drives the clockwise rotation of the long axis 61 wheel, the anticlockwise rotation of the left long axis 61 wheels drives the grille plates 62 to rotate to the right to be closed around the long axis 61, and the clockwise rotation of the right long axis 61 wheel drives the grille plates 62 to rotate to the left to be closed around the long axis 61. In this way, the memory strips 4 may be cooled. The wind blown by the cooling fans 51 enters into the wind scooper 52, the blown wind dissipates the heat of memory strips 4 and chips 41, In this way, a heat source may be used to cool the memory strips 4 and the chips 41 at the same time.

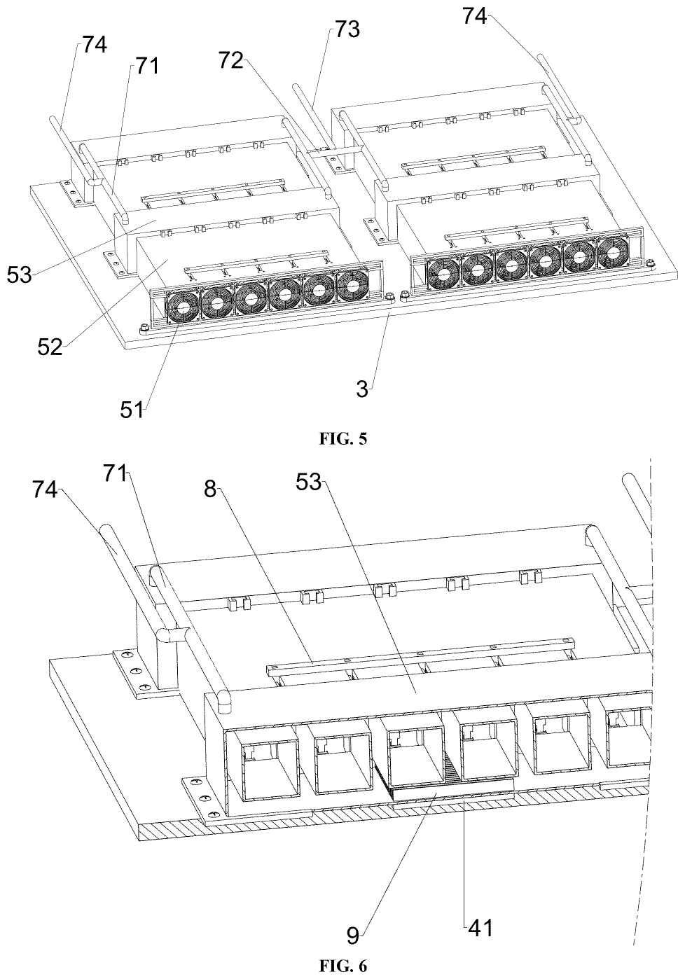

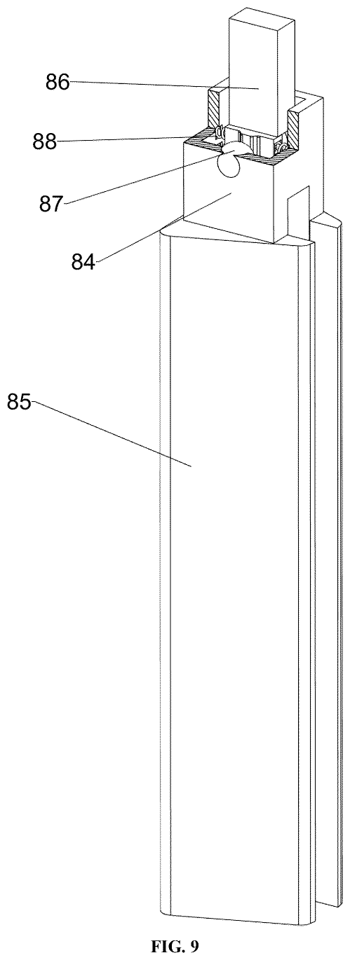

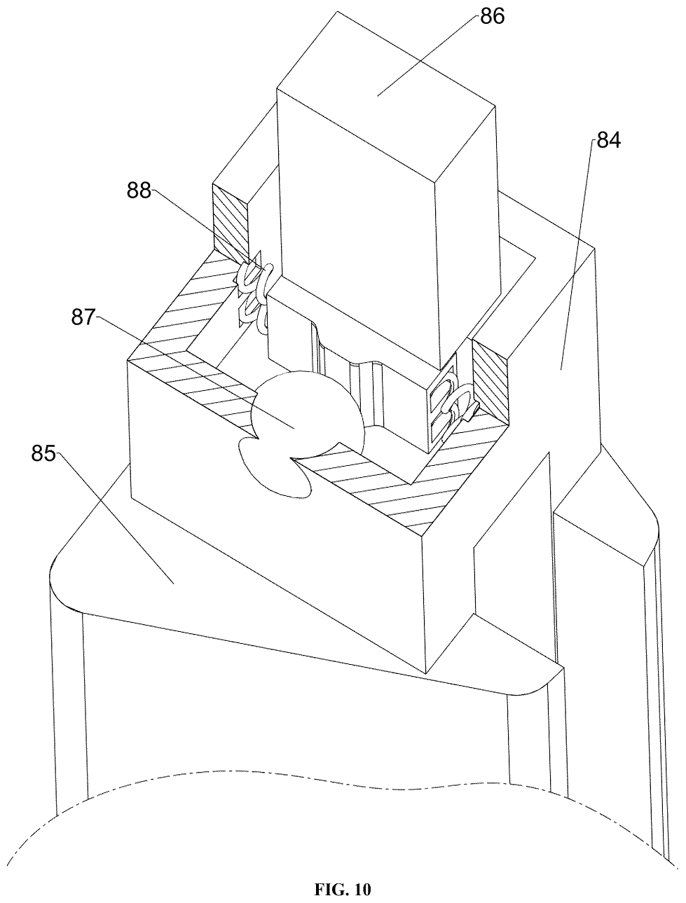

As shown in FIG. 5-FIG. 10, the liquid cooling cabinet further includes a water cooling device 7, the water cooling device 7 includes U-shaped pipes 71, a horizontal pipe 72, a straight pipe 73, L-shaped pipes 74, a water inlet vertical pipe 75, a water inlet pipe 76, a water outlet vertical pipe 77 and a water outlet pipe 78, U-shaped pipes 71 are arranged on the front and back two sides of the upper part of each six-hole heat-dissipation cavity device 53, the two U-shaped pipes 71 on the front side link and connect the front six-hole heat-dissipation cavity devices 53, the two U-shaped pipes 71 on the rear side link and connect the rear six-hole heat-dissipation cavity devices 53, the horizontal pipe 72 is arranged between the two U-shaped pipes 71 in the middle, the horizontal pipe 72 connects the two U-shaped pipes 71 in the middle, the middle right side of the horizontal pipe 72 is connected to the straight pipe 73, the front and rear U-shaped pipes 71 are connected to L-shaped pipes 74, the water inlet vertical pipe 75 is arranged at the front and back two sides of the right part of the cabinet 2, the water inlet vertical pipe 75 connects the longitudinal L-shaped pipes 74 on the front and back sides of the right part of the cabinet 2, the middle of the water inlet vertical pipe 75 is connected to the water inlet pipe 76, the water inlet pipe 76 discharges the external coolant in, the water outlet vertical pipe 77 is arranged in the middle of the right side of the cabinet 2, the water outlet vertical pipe 77 connects the longitudinal straight pipe 73 in the middle of the right side of the cabinet 2, the middle of the water outlet vertical pipe 77 is connected to the water outlet pipe 78, and the water outlet pipe 78 discharges the internal coolant out.

The liquid cooling cabinet further includes a wind direction adjusting device 8, the wind direction adjusting device 8 includes rotation shafts 81, guide plates 82, torsion springs 83, sliders 85, limit blocks 84, fixture blocks 86, spheres 87, small springs 88, and long blocks 89, ten rotation shafts 81 are rotatably arranged under each wind scooper 52, every two rotation shafts 81 are located on both sides of the front and back of one spacer plate 54, the guide plate 82 is fixedly arranged on each rotation shaft 81, the torsion spring 83 is arranged between the guide plate 82 and the wind scooper 52, the slider 85 is arranged in the sliding groove of each wind scooper 52, the upper part of the slider 85 is open setting, the limit block 84 is fixedly connected to the bottom of each slider 85, the limit block 84 is used to adjust an angle of the guide plate 82, the fixture block 86 is arranged at the upper opening of the slider 85, the bottom of the fixture block 86 is arranged to be wide in the middle and narrow on both sides, the spheres 87 are arranged on both sides of the fixture block 86, the spheres 87 pass through the front and rear sides of the slider 85, the small springs 88 are arranged between the left and right sides of the fixture block 86 and the left and right sides of the interior of the slide 85, one long block 89 is arranged on the upper part of each wind scooper 52, and each long block 89 connects five sliders 85 in the sliding groove of the lower wind scooper 52, the long block 89 is used to synchronously control five sliders 85, two circular holes 810 are arranged on both sides of the sliding groove of each wind scooper 52, and the circular holes 810 are matched with the spheres 87 in the sliders 85.

The liquid cooling cabinet further includes heat transfer fins 9, the heat transfer fins 9 are arranged at the inner bottom of the six-hole heat-dissipation cavity device 53 on each main board 3, the heat transfer fins 9 are located directly above each chip 41, and thermal conductive materials are coated between the chip 41 and the six-hole heat-dissipation cavity device 53.

The liquid cooling cabinet further includes a bracket 10, the middle of the right part of the cabinet 2 is arranged with the bracket 10 by bolts, and the bracket 10 fixes the water inlet pipe 76 and the water outlet pipe 78, which may effectively avoid the damage to the water inlet pipe 76 and the water outlet pipe 78 when moving the cabinet 2.

When it is necessary to reduce the wind temperature blowing out of cabinet 2 so that it does not cause load to the surrounding environment of cabinet 2, the inlet pipe 76 is connected from the outdoor to the coolant, the coolant is discharged into the water inlet vertical pipe 75 from the right the inlet pipe 76, and diverted from the water inlet vertical pipe 75 to each L-shaped pipe 74 on the front and rear sides, then discharged into each U-shaped pipe 71 on the front and rear sides through the L-shaped pipe 74, and then discharged from the front and back sides of the U-shaped pipe 71 into the six-hole heat-dissipation cavity device 53, when the coolant flows in the left side of the six-hole heat-dissipation cavity device 53, the left wind wind scooper 52 cools the hot wind blown by the memory strips 4 after cooling; and when the coolant flows in the right side of the six-hole heat-dissipation cavity device 53, the right wind wind scooper 52 cools the hot wind blown by the memory strips 4 after cooling; the flow in the six-hole heat-dissipation cavity device 53 cools the hot wind and discharges the wind from the middle part of the U-shaped pipes 71, the wind converges from the middle part of the U-shaped pipes 71 to the horizontal pipe 72, and then flows from the horizontal pipe 72 to the straight pipe 73, the wind gathers from the straight pipe 73 to the outlet vertical pipe 77, and then flows from the outlet vertical pipe 77 to the outdoor through the outlet pipe 78. In this way, the hot wind after the heat dissipation of the memory strips 4 may be cooled, and then blown out of the cabinet 2, without causing load to the surrounding environment of the cabinet 2. In this way, while the same heat dissipation source dissipates the heat of memory strips 4 and chips 41, the coolant may be discharged into through the water inlet pipe 76 to cool the air after heat dissipation, reduce the temperature of the air and discharge it outside the cabinet 2, so as not to affect the indoor temperature and not to cause load to the surrounding environment of the cabinet 2.

The operator moves the long blocks 89 to the left, the long blocks 89 move to the left to drive the fixture blocks 86 to move to the left, after the fixture blocks 86 move to the left, the fixture blocks are separated from the spheres 87, the small springs 88 at the left of the fixture blocks 86 are compressed, and the small springs 88 at the left of the fixture blocks 86 are stretched, the fixture blocks 86 move to the left to drive the sliders 85 to move to the left, and the sliders 85 move to the left to drive the limit blocks 84 to move to the left, at the same time, the spheres 87 are separated from the right circular holes 810, and the circular holes 87 on the front and rear sides of the fixture blocks 86 are separated from the circular holes 810 and move to the sliders 85 by the limit of the sliding grooves, when the sliders 85 moves to the left, the limit blocks at the lower front of the the sliders move to the left to squeeze the spacer plates 82 at the front of the spacer plates 54, so that the guide plates 82 rotate clockwise along the rotation shaft 81, at the same time, the torsion springs 83 exert torsion on the guide plates 82, the spacer plates 82 direct the wind to the front side of the memory strips 4 to cool the wind, the limit blocks 84 at the lower rear of the sliders move to the left to squeeze the spacer plates 82 at the front of the spacer plates 54, the spacer plates 82 rotates counterclockwise along the rotation axis 81, at the same time, the torsion springs 83 exert torsion on the guide plates 82, the spacer plates 82 direct the wind to the rear side of the memory strips 4 to cool the wind, when the sliders 85 move to the most left side of the sliding grooves, the long blocks 89 are loosened, and the fixture blocks 86 are reset under the action of the small springs 88 on the left and right of the fixture blocks, the fixture blocks 86 push the spheres 87 forward and backward on both sides, so that the spheres 87 are re-clamped into the left circular holes 810. In this way, the wind may be guided the front and back sides of the memory strips 4 to cool down, and further strengthen the heat dissipation effect of the memory strips 4. When the operator moves the long blocks 89 to the right, the long blocks 89 move to the right to drive the fixture blocks 86 to move to the right, and after the fixture blocks 86 move to the right and the fixture blocks are separated from the spheres 87, the small springs 88 on the right side of the fixture blocks 86 are compressed, and the small springs 88 on the left side of the fixture blocks 86 is stretched, the fixture blocks 86 move to the right to drive the sliders 85 to move to the right, and the sliders 85 move to the right to drive the limit blocks 84 to move to the right, at the same time, the spheres 87 are separated from the left circular holes 810, and the spheres 87 are separated from the circular holes 810 and move to the sliders 85 by the limit of the sliding grooves, when the sliders 85 move to the most right side of the sliding grooves, the limit blocks 84 are separated from the guide plates 82, and then the long blocks 89 are loosened, the fixture blocks 86 are reset under the action of the small springs 88 on the left and right of the fixture blocks, the fixture blocks 86 push the spheres 87 forward and backward on both sides, so that the spheres 87 are re-clamped into the right circular holes 810, and the guide plates 82 are reset under the action of the torsion springs 83. In this way, the flow direction of the wind may be changed, so that the hot wind may be discharged faster. By pushing the long blocks 89 to change the blowing direction of the wind, the heat dissipation effect on the memory strips 4 may be enhanced or the hot wind may be discharged faster.

Through the heat transfer fins 9 arranged at the bottom of the inner side of the six-hole heat-dissipation cavity devices 53, the contact area with the coolant is increased, and the chips 41 on the main board 3 may be better dissipated.

Through the bracket 10 arranged in the middle of the right side of the cabinet 2, it may effectively avoid damage to the water inlet pipe 76 and the water outlet pipe 78 when moving the cabinet 2.

Finally, it is to be noted that the above is only a preferred embodiment of the present disclosure and is not used to limit the present disclosure. Although the present disclosure is described in detail with reference to the aforementioned embodiments, it is still possible for technicians in the field to modify the technical solutions recorded in the aforementioned embodiments, or to equivalently replace some of the technical features. Any modification, equivalent replacement, improvement, etc. made within the spirit and principles of the present disclosure shall be included in the scope of protection of the present disclosure.

What is claimed is:

1. A new type of a high-efficiency liquid cooling cabinet for a data center server, comprising a base plate, a cabinet, main boards, memory strips, and chips, wherein the cabinet is welded on an upper part of the base plate, front, left, and right sides of the cabinet are open settings, seven main boards are evenly distributed in the cabinet up and down, four groups of the memory strips are arranged on each of the seven main boards, the memory strips are grouped into six, two chips are arranged on each of the seven main boards symmetrically in front and back; and the new type of the high-efficiency liquid cooling cabinet for the data center server further comprises air cooling devices and air inlet regulating devices, wherein each of the seven main boards is arranged with one air cooling device to dissipate heat from the seven main boards, the air inlet regulating devices are arranged on the left and right sides of the cabinet, and left and right air intake volume is allowed to be adjusted by the air inlet regulating devices.

2. The new type of the high-efficiency liquid cooling cabinet for the data center server according to claim 1, wherein the air cooling device comprises cooling fans, wind scoopers, six-hole heat-dissipation cavity devices, and spacer plates, two groups of the cooling fans are arranged on an upper left side of each of the seven main boards, the cooling fans are grouped into six, four wind scoopers are arranged on each of the seven main boards, the wind scooper covers each of the four groups of the memory strips, the wind scooper draws wind from left to right, five sliding grooves are arranged on an upper part of the wind scooper, each of the seven main boards is arranged with four six-hole heat-dissipation cavity devices, the six-hole heat-dissipation cavity devices are located on a right side of each of the four groups of the memory strips, an interior of the six-hole heat-dissipation cavity device is allowed to be configured for a cooling liquid circulation, each of the four wind scoopers is arranged with five spacer plates, and each of the five spacer plates is located between every two memory strips.

3. The new type of the high-efficiency liquid cooling cabinet for the data center server according to claim 2, wherein the air inlet regulating device comprises long axes, grille plates, column wheels, racks, circular shafts, missing-tooth wheels, and deflector rods, wherein
left and right openings of the cabinet are evenly distributed with the long axes in a longitudinal direction, the long axes are arranged horizontally, both ends of the long axes are embedded in the cabinet, one grille plate is fixedly arranged on each of the long axes, one column wheel is fixed at each of both ends of each of the long axes, two racks are arranged in the left and right openings of the cabinet in a sliding type, respectively, each of the two racks is engaged with the column wheel longitudinally distributed at an end of a corresponding long axis, one circular shaft is arranged on an upper side of each of the two racks facing outward, one missing-tooth wheel is rotatably arranged on the circular shaft, a toothed side of the missing-tooth wheel is engaged with each of the two racks, a missing-tooth side of the missing-tooth wheel is fixedly connected to one deflector rod, the deflector rod is configured to shift the missing-tooth wheel, and the deflector rod penetrates out of the cabinet.

4. The new type of the high-efficiency liquid cooling cabinet for the data center server according to claim 3, wherein the high-efficiency liquid cooling cabinet further comprises a water cooling device, the water cooling device comprises U-shaped pipes, a horizontal pipe, a straight pipe, L-shaped pipes, a water inlet vertical pipe, a water inlet pipe, a water outlet vertical pipe, and a water outlet pipe, wherein
the U-shaped pipes are arranged on front and rear two sides of an upper part of each of the four six-hole heat-dissipation cavity devices, two U-shaped pipes on the front side link and connect front six-hole heat-dissipation cavity devices, two U-shaped pipes on the rear side link and connect rear six-hole heat-dissipation cavity devices, the horizontal pipe is arranged between two U-shaped pipes in middle, the horizontal pipe connects the two U-shaped pipes in the middle, a middle right side of the horizontal pipe is connected to the straight pipe, front and rear U-shaped pipes are connected to the L-shaped pipes, the water inlet vertical pipe is arranged at front and rear two sides of a right part of the cabinet, the water inlet vertical pipe connects longitudinal L-shaped pipes on the front and rear two sides of the right part of the cabinet, a middle of the water inlet vertical pipe is connected to the water inlet pipe, the water inlet pipe discharges an external coolant in, the water outlet vertical pipe is arranged in a middle of the right side of the cabinet, the water outlet vertical pipe connects a longitudinal straight pipe in the middle of the right side of the cabinet, a middle of the water outlet vertical pipe is connected to the water outlet pipe, and the water outlet pipe discharges an internal coolant out.

5. The new type of the high-efficiency liquid cooling cabinet for the data center server according to claim 4, wherein the high-efficiency liquid cooling cabinet further comprises a wind direction adjusting device, the wind direction adjusting device comprises rotation shafts, guide plates, torsion springs, sliders, limit blocks, fixture blocks, spheres, small springs, and long blocks, wherein ten rotation shafts are rotatably arrange under each of the four wind scoopers, every two rotation shafts are located on both sides of front and back of one spacer plate, the guide plate is fixedly arranged on each of the ten rotation shafts, the torsion springs is arranged between the guide plate and the wind scooper, the slider is arranged in the sliding groove of each of the four wind scoopers, an upper part of the slider is open setting, the limit block is fixedly connected to a bottom of each of the sliders, the limit block is configured to adjust an angle of the guide plate, the fixture block is arranged at an upper opening of the slider, a bottom of the fixture block is arranged to be wide in middle and narrow on both sides, the spheres are arranged on the both sides of the fixture block, the spheres pass through front and rear sides of the slider, the small springs are arranged between left and right sides of the fixture block and left and right sides of an interior of the slider, one long block is arranged on the upper part of each of the four wind scoopers, and each of the long blocks connects five sliders in a sliding groove of a lower wind scooper, the long block is configured to synchronously control the five sliders, two circular holes are arranged on both sides of the sliding groove of each of the four wind scoopers, and the two circular holes are matched with the spheres in the sliders.

6. The new type of the high-efficiency liquid cooling cabinet for the data center server according to claim 5, wherein the high-efficiency liquid cooling cabinet further comprises heat transfer fins, the heat transfer fins are arranged at an inner bottom of the six-hole heat-dissipation cavity device on each of the seven main boards, the heat transfer fins are located directly above each of the chips, and thermal conductive materials are coated between the chip the six-hole heat-dissipation cavity device.

7. The new type of the high-efficiency liquid cooling cabinet for the data center server according to claim 6, wherein the high-efficiency liquid cooling cabinet further comprises a bracket, a middle of the right part of the cabinet is arranged with the bracket by bolts, and the bracket fixes the water inlet pipe and the water outlet pipe, wherein the bracket is allowed to effectively avoid a damage to the water inlet pipe and the water outlet pipe when moving the cabinet.
